(19) United States
(12) Patent Application Publication
(10) Pub. No.: US 2006/0157101 A1
(43) Pub. Date: Jul. 20, 2006

(54) System and method for fabrication of high-efficiency durable thermoelectric devices

(76) Inventors: Jeff S. Sakamoto, San Gabriel, CA (US); G. Jeffrey Snyder, Altadena, CA (US); Thierry Calliat, Pasadena, CA (US); Jean-Pierre Fleurial, Altadena, CA (US); Steven M. Jones, La Crescente, CA (US); Jong-Ah Palk, Pasadena, CA (US)

Correspondence Address: TOPE-MCKAY & ASSOCIATES, 23852 PACIFIC COAST HIGHWAY #311, MALIBU, CA, 90265, US

(21) Appl. No.: 11/300,632

(22) Filed: Dec. 13, 2005

Related U.S. Application Data
(63) Continuation-in-part of application No. 10/977,276, filed on Oct. 29, 2004.

(51) Int. Cl. F25B 21/02; H01L 37/00; H01L 35/34

(52) U.S. Cl. 136/201; 62/3.7

(57) ABSTRACT

The present invention relates to a durable high-efficiency thermoelectric device. More specifically, the present invention relates to a thermoelectric device formed with a novel thermoelectric material and system which incorporates a vaporizable scaffolding to create microscopic gaps between the thermoelectric elements which are filled with a high-density, shrink-resistant aerogel.

### PRIORITY CLAIM

The present application is a continuation-in-part of U.S. application Ser. No. 10/977,276, filed Oct. 29, 2004, now pending, entitled “System and Method for Sublimation Suppression Using Opacified Aerogel,” and claims the benefit of priority of U.S. Provisional Patent Application No. 60/635,870, filed Dec. 13, 2004, and entitled “Diffusion Bonding Thermoelectric Devices Using the Molybdenum-Titanium Eutectoid Reaction,” and U.S. Provisional Patent Application No. 60/691,543, filed Jun. 17, 2005, and entitled “A Process for Integrating High Density Aerogel Into Thermoelectric Devices.”

### STATEMENT OF GOVERNMENT INTEREST

This invention described herein was made in the performance of work under a NASA contract, and is subject to the provisions of Public Law 96-517 (35 USC 202) in which the Contractor has elected to retain title.

### BACKGROUND OF THE INVENTION

(1) Technical Field

The present invention relates to a durable high-efficiency thermoelectric device. More specifically, the present invention relates to a thermoelectric device formed with a novel thermoelectric material and process that incorporates a vaporizable scaffolding to create microscopic gaps between thermoelectric elements; the gaps are then filled with a high-density, shrink-resistant aerogel.

(2) Background

Thermoelectric devices are attractive options for the generation of electricity and refrigeration because of their high reliable, silent, vibration-free operation; lack of compressed gases, chemicals, or other consumables; and complete scalability. Thermoelectric materials have been employed in space to power the Apollo, Viking, Pioneer and Voyager space missions, and are currently used in automotive seat cover coolers, in portable refrigerators that plug into an automobile's cigarette lighter, and in chemical and nuclear generators in artic regions and space probes.

Thermoelectric devices work by naturally generating a temperature gradient in the presence of an electromotive force (emf); conversely they produce an emf in a temperature gradient. While all materials except superconductors posses some thermoelectric character, only a few materials are efficient enough to generate interest. These include the lead, bismuth, and antimony chalcogenides, skutterudites (such as cobalt triantimonide), bismuth antimony, silicon germanium, boron carbides, and more complex compounds and alloys based on these materials.

One example of a thermoelectric device is a thermoelectric refrigerator. A thermoelectric refrigerator connects two or more pieces of thermoelectric material to a voltage source. One skilled in the art will appreciate that a generator can be made from the same device if the voltage source is replaced by a load (i.e., a battery charger). Nearly all thermoelectric devices use two different types of materials, one “n-type” and the other “p-type.” These materials must be electrically connected in series, but thermally connected in parallel.

A specific example of a thermoelectric device is shown in FIG. 1 (prior art).

In this example, the thermoelectric generators/coolers 100 employ elements or legs 102 with high aspect ratios. To efficiently generate power or cool, the legs should be shielded with insulation 104 so that heat flows through the legs rather than being radiated laterally outward 106.

As thermoelectric devices run at high current and low voltage, the circuitry connecting thermoelectric elements must not significantly add to the internal resistance of the device. Similarly, the circuitry must be chemically and mechanically stable over time to assure years to decades of maintenance-free operation.

One drawback of the prior art is degradation of the thermoelectric material by sublimation. Sublimation is a degradation mechanism, which can rapidly diminish the performance of a thermoelectric power generation process. Practically all thermoelectric materials for use in power generation are susceptible to the sublimation of one or more of their respective elements. Germanium subliming from SiliconGermanium (SiGe) technology, Antimony subliming from Skutterudite-based technology, and Tellurium subliming from PbTe-TAGS technology are examples of thermoelectric technologies that are susceptible to sublimation, leaving them vulnerable to eventual performance degradation. It has been previously shown that sublimation of antimony (Sb) from advanced, skutterudite thermoelectric materials (such as CoSb₃ and CeFe₃0.5Co0.5Sb₁₂) degrades device performance. It has also been shown that the sublimation of Sb could be suppressed by the application of robust, micron-scale coatings. These coatings consisted of thin metal foils of titanium or molybdenum. Although the films were thin enough to minimize thermal and electrical shorting, which can potentially diminish performance, coatings that are both electrically and thermally insulating are preferred.

Thus, what is needed is a system and method that reduces sublimation of thermoelectric device components, thus extending the life and durability of thermoelectric devices formed thereform.

Aerogel is a silicon-based solid with a porous, sponge-like structure in which 99.8 percent of the volume is empty space. In comparison to glass, also a silicon-based solid, aerogel is 1,000 times less dense. Additionally, aerogel has extreme microporosity on a micron sale. It is composed of individual features only a few nanometers in size. These are linked in a highly porous dendritic-like structure.

Aerogel has properties such as low thermal conductivity, low refractive index and low sound speed. Aerogel is made by hig-temperature and pressure-critical drying of a gel composed of colloidal silica structural units filled with solvents. Aerogel is available from Jet Propulsion Laboratory (Pasadena, Calif.).

Aerogel can be an excellent sublimation suppression barrier and thermal insulation for thermoelectric power generation system due to its unique structure. The best way to incorporate aerogel is to cast aerogel around a device or individual thermoelectric modules. However, shrinkage during gelation and supercritical drying causes cracking and makes it difficult to incorporate aerogel into the system. Minimizing shrinkage of aerogel is a key factor to enable casting of aerogel in and around the elements. When attempting to suppress sublimation, it is advantageous to make aerogels with higher densities (>100 mg/cc). However, shrinkage of aerogel generally increases as the density of aerogel increases, which typically results in cracked coatings. Because of its unique properties, aerogels can be a good sublimation barrier. Aerogel possesses a torturous pathway for vapor transport and the average pore size of aerogel is several orders of magnitude lower than the mean free path of, for example, Antimony (Sb) vapor under predicted operation conditions (700 C and 10⁻⁶ Torr). Sublimation suppression of aerogel coatings can improve further if aerogel is composed of smaller pores with a narrow pore size distribution, which is generally achieved with increased density.

Therefore, what is needed is a high-density aerogel compound that does not experience shrinkage and cracking during formation.

Previously, the Space Power 100 (“SP100”) program developed modules employing SiGe thermoelectric technology. SP100 TEMs consist of SiGe thermoelectric elements, which were electrically insulated/separated by an alkali glass. The glass was approximately 100 microns thick and was chemically bound to the surface of each SiGe element such that it also served as “glue” between the elements. Additionally, the glass coating prevented or slowed sublimation of Ge and dopants. Through the course of the SP100 development it was found that an issue involving the use of this glass resulted in recommendations to eliminate it. The issue involved module failures attributed to voids in the glass, which resulted from contamination. The primary contaminant was potassium (K), a dopant, which diffused through the alkali glass thus changing the coefficient of thermal expansion (CTE). The change in CTE resulted in substantial stresses, which ultimately resulted in component fracture. As a result, strong recommendations were made to prepare modules without glass “glue” between thermoelectric legs. Instead, vacuum gaps between the legs are preferred. With vacuum gaps electric insulation will not be an issue since the legs are not in contact, but sublimation will occur if the legs are not coated. The challenge then is how to fabricate efficient, durable thermoelectric modules with vacuum gaps between the legs while simultaneously suppressing sublimation of volatile elements.

### SUMMARY OF THE INVENTION

The present invention provides a system and a method that overcomes the aforementioned limitations and fills the aforementioned needs by providing a castable, aerogel-based, ultra-low thermal conductivity opacified insulation to suppress sublimation.

In one aspect, a durable high-efficiency thermoelectric device comprises a thermoelectric skutterudite device bonded with a strong, low-contact resistance, high-temperature bond on a hot-side interconnect.

The durable high-efficiency thermoelectric device wherein the thermoelectric skutterudite device is bonded using a eutectoid reaction of powders selected from the group consisting of titanium and molybdenum (Ti—Mo), titanium-niobium (Ti—Nb), titanium-palladium (Ti—Pd), and titanium-graphite.

The durable high-efficiency thermoelectric device wherein the thermoelectric skutterudite device is bonded using a eutectoid reaction of pre-formed plates selected from the group consisting of titanium and molybdenum (Ti—Mo), titanium-niobium (Ti—Nb), titanium-palladium (Ti—Pd), and titanium-graphite.

A method for fabricating durable high-efficiency thermoelectric devices comprising acts of inserting a plate into an opening of a graphite die; pressing a first thermoelectric leg onto the plate through a press hole in the graphite die to create a bond between the first thermoelectric leg and the plate; removing the plate and now bonded first thermoelectric leg and rotating the plate before reinserting the plate into the graphite die, wherein the first thermoelectric leg is inserted into a relief hole in the graphite die; and pressing a second thermoelectric leg onto the plate through the press hole to create a bond between the second thermoelectric leg and the plate.

The method for fabricating durable high-efficiency thermoelectric devices wherein the thermoelectric skutterudite device is formed using a hot press applying approximately 100 MegaPascals (MPa) of pressure at approximately 700 degrees Celsius (C.).

The method for fabricating durable high-efficiency thermoelectric devices wherein the thermoelectric skutterudite device is formed using a plate press applying only approximately 1 MPa of pressure at approximately 700 C.

The method for fabricating durable high-efficiency thermoelectric devices wherein the plate is made of molybdenum.

The method for fabricating durable high-efficiency thermoelectric devices wherein the first thermoelectric leg is formed of an n-type material.

The method for fabricating durable high-efficiency thermoelectric devices wherein the first thermoelectric leg is formed of titanium, n-type skutterudite, titanium powder and nickel powder.

The method for fabricating durable high-efficiency thermoelectric devices wherein the second thermoelectric leg is formed of a p-type material.

The method for fabricating durable high-efficiency thermoelectric devices wherein the second thermoelectric leg is formed of titanium, cobalt, p-type skutterudite, titanium and nickel.

A high density shrink-resistant aerogel comprising a composite aerogel primarily comprised of an oxide powder to prevent shrinkage during formation in a supercritical drying process.

The high density shrink-resistant aerogel wherein the density of the composite aerogel is greater than 100 milligrams per cubic centimeter (mg/cc).

The high density shrink-resistant aerogel wherein the composite aerogel is formed from tetraethylorthosilicate (“TEOS”), ethanol, nitric acid, and titania powder.

The high density shrink-resistant aerogel wherein the titania powder is comprised roughly micrometer-sized particles.

A method for creating a gap between thermoelectric legs comprising an act of forming a vaporizable scaffold around a portion of a thermoelectric leg during formation of a thermoelectric element, wherein the vaporizable scaffold vaporizes during the formation of the thermoelectric element to create a gap separating a first thermoelectric leg from a second thermoelectric leg, such that the gap can be filled with an insulating material.

The method for creating a gap between thermoelectric legs wherein the vaporizable scaffold comprises a polymer.

The method for creating a gap between thermoelectric legs wherein the polymer is Poly-α-methylstyrene (“PAMS”).

The method for creating a gap between thermoelectric legs wherein the insulating material is an aerogel.

### BRIEF DESCRIPTION OF THE DRAWINGS

The objects, features and advantages of the present invention will be apparent from the following detailed descriptions of the disclosed aspects of the invention in conjunction with reference to the following drawings, where:

FIG. 1 is a prior art representation of a castable aerogel-based insulation placed around a thermoelectric device;

FIG. 2 is an illustration of a custom machined graphite die used to simultaneously bond titanium powder on a molybdenum plate;

FIG. 3 is a chart of temperature and pressure versus time profile used for hot pressing;

FIG. 4 is a photograph of a Scanning Electron (BSE) and Optical Micrographs of a Titanium-Molybdenum Solid-Solution (TMSS) interphase at 1, 4, 8 and 12 weeks at a temperature of 700 degrees Celsius (C.);

FIG. 5 is an illustration of the process for fabricating a thermoelectric unicouple using a custom-designed graphite die, depicting the two-step process where one thermoelectric leg is pressed and bonded to a Molybdenum plate, subsequently removed, rotated 180 degrees and re-inserted in the die to bond a second thermoelectric leg;

FIG. 6 is a photograph of a novel Skutterudite unicouple with a stable, hot-side interconnect prepared with a hot press process;

FIG. 7 is a chart depicting contact resistance measurements of a Titanium-Molybdenum coupon;

FIG. 8 is a photograph of a low-pressure (1 MPa) bonding apparatus employing precision-guidance pins and a spring-loaded heater assembly;

FIG. 9 is a scanning electron micrograph image (back-scattered image) of a Molybdenum-Titanium coupon bonded at mechanical pressure of 1 MPa at a temperature of 740 C for 100 minutes under 10⁻⁶ torr vacuum;

FIG. 10 is a photograph of a novel Skutterudite unicouple with a stable, hot-side interconnect prepared with a low-pressure process;

FIGS. 11A-11D are a set of photographs depicting shrinkage of aerogels depending on the density of silica aerogel and the amount of solid powder;

FIG. 12 is a chart depicting the relationship of shrinkage in comparison with the density of aerogel;

FIG. 13A is a magnified scanning electron microscope (“SEM”) image of aerogels of various densities;

FIG. 13B is a magnified SEM image of a high-density aerogel mixed with a titania powder;

FIG. 14A is an illustration of an Antimony (“Sb”) sample in a graphite cup encapsulated with aerogel;

FIG. 14B is a chart depicting the results of a thermogravimetric analysis (“TGA”) comparing weight loss of antimony with and without an aerogel comprised of silica and titania powder;

FIG. 15 is an illustration of one embodiment of the process of using a polymer-based vaporizable scaffold sheet partially surrounding a thermoelectric leg such that the scaffold vaporizes upon heating, leaving a gap between the thermoelectric leg that can be filled with aerogel;

FIG. 16 is a chart illustrating the complete vaporization of Poly-α-methylstyrene (“PAMS”) between 250 C and 400 C;

FIG. 17A is an illustration of Molybdenum legs bound to a Titanium plate that were separated by a sheet of PAMS;

FIG. 17B is a set of photographs illustrating the how the PAMS vapor did not interfere with the bonding of Molybdenum and Titanium; and

FIG. 18 is an illustration of envisioned usage of the vaporizable scaffold, involving dicing n and p ingots into wafers. The wafers are then separated by PAMS sheets and stacked. A series of stacks, cuts and re-bonding produces a checker-board patterned array of thermoelectric legs ready for bonding to the metal pads on a ceramic substrate.

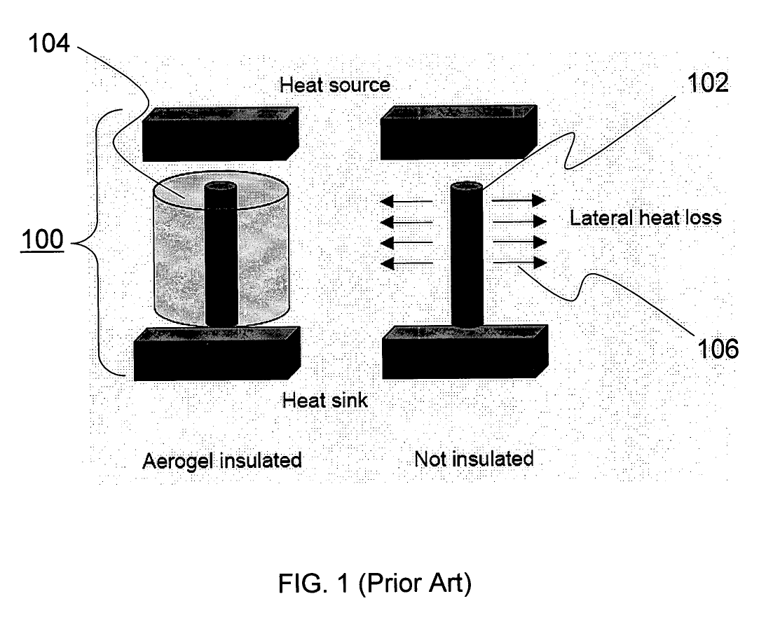

### DETAILED DESCRIPTION

The present invention relates to a durable high-efficiency thermoelectric device. More specifically, the present invention relates to a thermoelectric device formed with a novel thermoelectric material and system which incorporates a vaporizable scaffolding to create microscopic gaps between the thermoelectric elements which are filled with a high-density, shrink-resistant aerogel. The following description, taken in conjunction with the referenced drawings, is presented to enable one of ordinary skill in the art to make and use the invention and to incorporate it in the context of particular applications. Various modifications, as well as a variety of uses in different applications, will be readily apparent to those skilled in the art, and the general principles, defined herein, may be applied to a wide range of embodiments. Thus, the present invention is not intended to be limited to the embodiments presented, but is to be accorded the widest scope consistent with the principles and novel features disclosed herein. Furthermore, it should be noted that unless explicitly stated otherwise, the figures included herein are illustrated diagrammatically and without any specific scale, as they are provided as qualitative illustrations of the concept of the present invention.

In the following detailed description, numerous specific details are set forth in order to provide a more thorough understanding of the present invention. However, it will be apparent to one skilled in the art that the present invention may be practiced without necessarily being limited to these specific details. In other instances, well-known structures and devices are shown in block diagram form, rather than in detail, in order to avoid obscuring the present invention.

The reader's attention is directed to all papers and documents that are filed concurrently with this specification and are open to public inspection with this specification, and the contents of all such papers and documents are incorporated herein by reference. All the features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the claims herein is not intended to invoke the provisions of 35 U.S.C. 112, Paragraph 6.

The description given below sets forth a durable high-efficiency thermoelectric device. More specifically, the present invention relates to a thermoelectric device formed with a novel thermoelectric material and system which incorporates a vaporizable scaffolding to create microscopic gaps between the thermoelectric elements which are filled with a high-density, shrink-resistant aerogel.

(1) Diffusion Bonding Thermoelectric Devices

An important act in the process of fabricating high-efficiency, durable thermoelectric devices is the selection of circuitry. The circuitry connecting the thermoelectric elements must not significantly add to the internal resistance of the device. Similarly, the circuitry must be chemically and mechanically stable over time to assure years to decades of maintenance-free operation.

Bonding Molybdenum interconnect to thermoelectric legs is a novel solution to this problem, particularly for use at high temperatures (above 700 degrees Celsius (“C.”)).

The initial experiments used the optimum conditions (high temperature and pressure) to fabricate Titanium/Molybdenum coupons for evaluation. This was achieved through the use of a hot press capable of applying 100 megapascals (“MPa”) pressure and a temperature >700 C in an inert argon atmosphere to prevent oxidation.

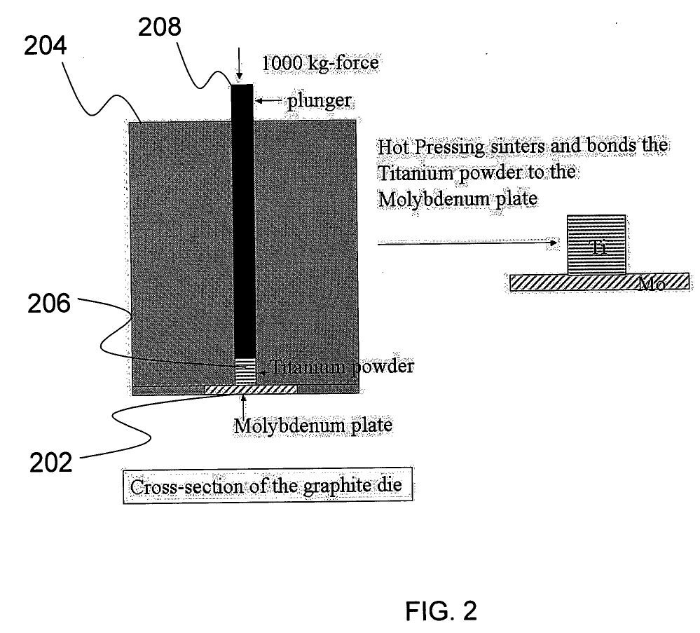

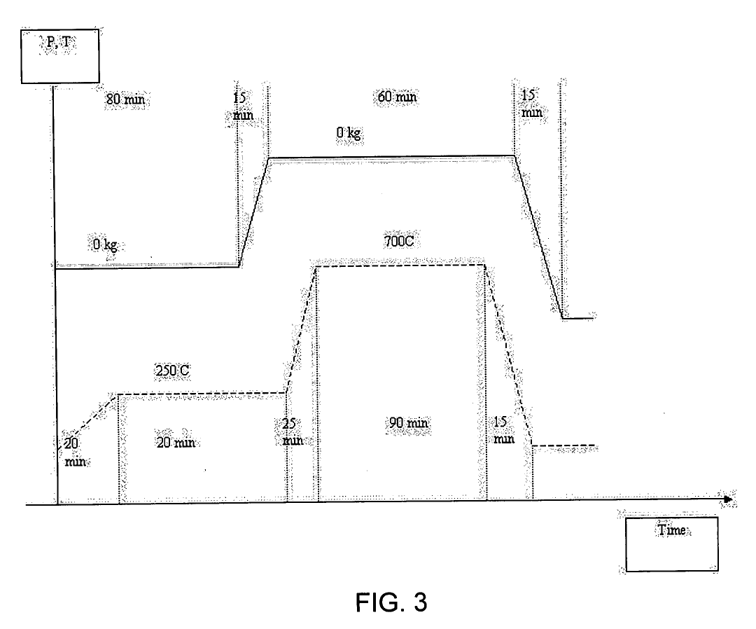

In one embodiment, commercially available Molybdenum plate 202 (2.0 millimeters (“mm”) thick, 1.1 mm wide and 40 mm long (Rembar® Inc., Dobbs Ferry, N.Y. 10522)) was placed in a specifically designed Poco® graphite die 204 (Poco Graphite, Inc., Decatur, Tex. 76234), as illustrated in FIG. 2. To remove residual stress (which can cause embrittlement), the Molybdenum plate 202 was annealed at 1200 C in a sealed quartz ampoule for 1 hour. Also, the Molybdenum plate 202 was roughened with 600 grit sandpaper and cleaned in acetone before bonding. The 8.0 mm bore die 204 shown in FIG. 2 had a slot machined in the bottom to accommodate the Molybdenum plate 202, which was placed in the slot at the bottom of the graphite die 204. 100 milligrams (“mg”) of Titanium powder 206 was loaded into the die such that it lay on top of the Molybdenum plate 202. A plunger 208 was inserted in the bore and the Titanium powder was pressed and heated using the Time-Temperature-Pressure profile in FIG. 3.

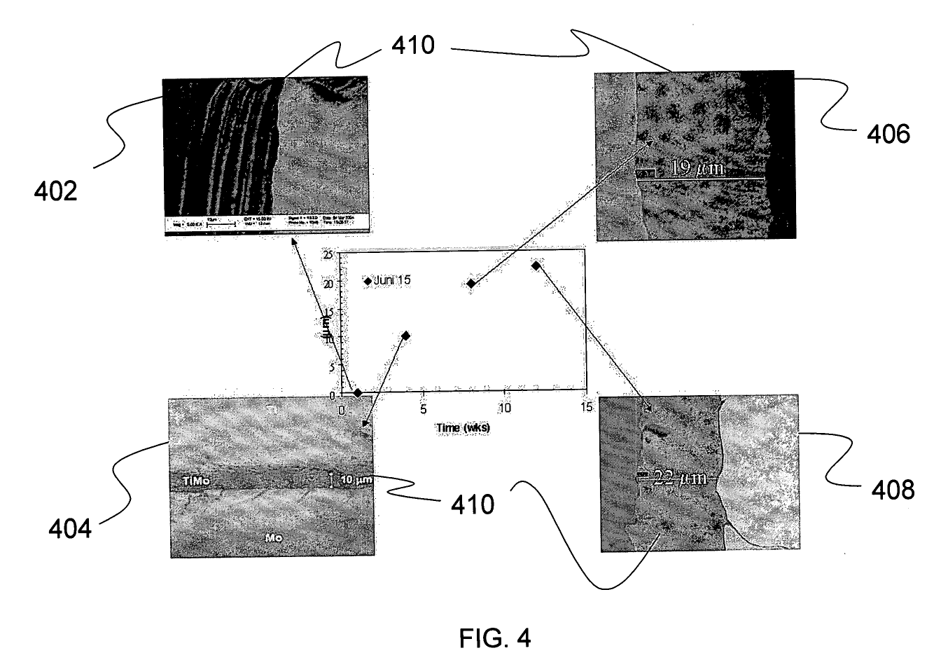

The resulting coupon was a cylinder of Titanium bonded to a Molybdenum plate. To characterize the stability of the bond, samples were: (i) cut in half down the longitudinal axis of the Titanium cylinder, (ii) heated in an evacuated ampoule at the predicted operating temperature of the bond (700 C) for predetermined intervals, and (iii) characterized using an Scanning Electron Miscroscope (“SEM”) at the end of each interval. Several samples went through this process all with consistent results. A particular data set from one sample is reported here as an example and depicted in the photographs in FIG. 4. This particular sample was heated over twelve weeks and the interface/inter-diffusion zone was measured at one 402, four 404, eight 406 and twelve 408 weeks. Overall, the bonds were excellent, crack-free bonds and appeared to be stable with time at the predicted operating temperature. The thickness of the reaction zone 410 was negligible after one week, but was noticeable after four weeks. The reaction zone consisted of a Titanium-Molybdenum Solid-Solution (“TMSS”) bond, which is a mix of Titanium and Molybdenum that formed a single-solution phase with no intermetallics. Additionally, the thickness of the TMSS zone was relatively thin even after 12 weeks 408 (approximately 20 microns), and the rate of growth appears to slow with time, thus demonstrating long term stability.

(A) Fabricating Thermoelectric Unicouples using the Titanium/Molybdenum Eutectoid Reaction under High Pressure (100 MPa using a Hot-Press)

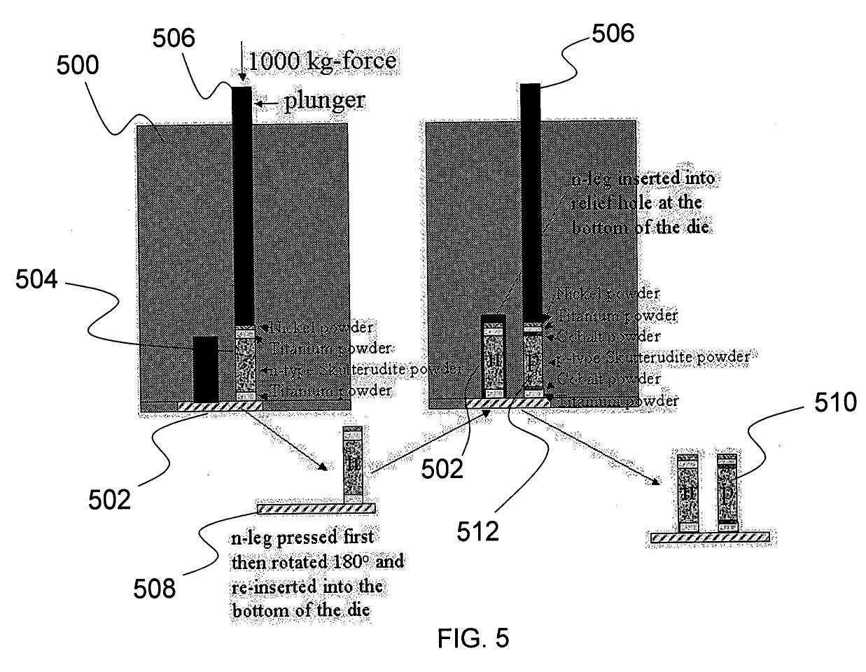

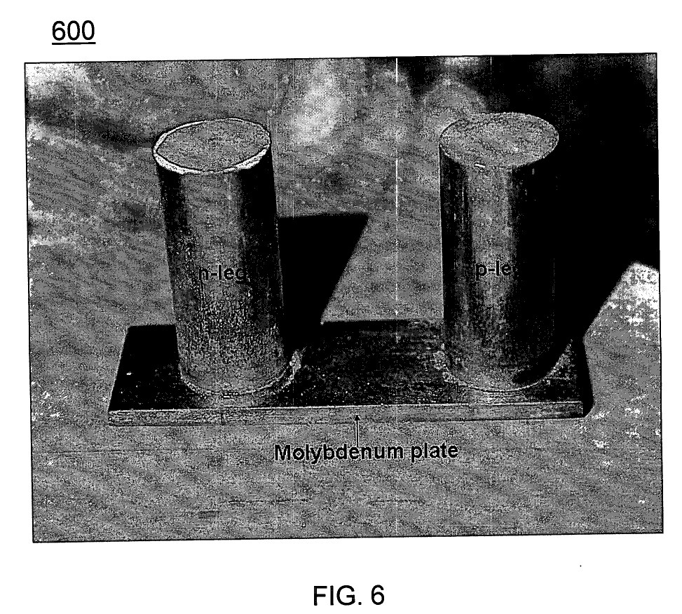

Skutterudite-based thermoelectric unicouples were fabricated using the same graphite die shown in FIG. 2 (now illustrated in FIG. 5). A Molybdenum plate 502 was placed in the slot at the bottom of a graphite die 500. The die 500 was loaded with powders in the following order: 100 mg of Titanium, six grams of n-type Skutterudite, 100 mg of Titanium powder and 50 mg of Nickel powder. The stack of powders 504 was pressed using the same plunger 506 and profile as before and the sample was extracted as described in the previous section, but this time the n-leg/Molybdenum assembly 508 was rotated 180 degrees and re-inserted in the die 500 to bond the p-type leg 510 to the Molybdenum plate 502. The die 500 was then loaded with powder 512 in the following order: 100 mg of Titanium, 200 mg of Cobalt, 6 grams of p-type Skutterudite, 100 mg of Titanium and finally 50 mg of Nickel. The sample was again pressed using the plunger 506 and profile as described above. The resulting unicouple 600 shown in FIG. 6 is the first report of a Skutterudite unicouple bonded with a strong, low-contact resistance high-temperature bond on the hot-side interconnect.

(B) Electrical Contact Resistance Characterization

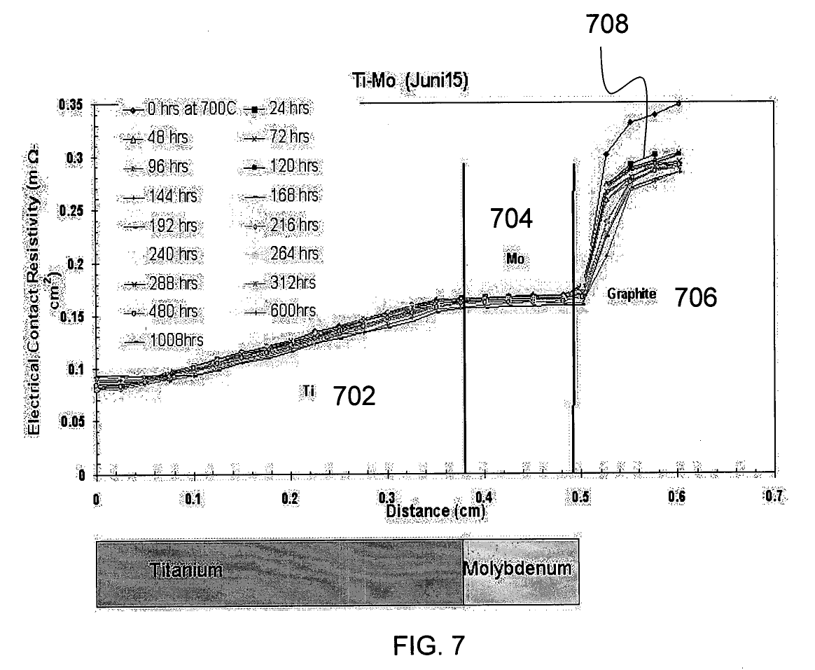

One of the most critical aspects of thermoelectric device performance involves low contact-resistance interconnects. Ideally, the interfacial resistance should be far lower than the thermoelectric element contribution. To evaluate the contact resistance of the TMSS bond a Titanium/Molybdenum couple (as shown in FIG. 4) was tested in an apparatus that measures electrical resistance as a function of distance along the sample while at 700 C. The data shown in the chart in FIG. 7 indicates that the resistance of the interface was negligible and stable over 1000 hours of testing. The contact probe scans started on the Titanium end 702 and traversed the surface in 250-micron increments. The scans passed over the TMSS interphase over the Molybdenum 704 and ended in a pressure contact graphite electrode 706. The jump in resistance 708 between the Molybdenum and pressure-contacted graphite is typical and irrelevant. Additionally, this experiment is another method of evaluating bond stability/integrity and as such clearly demonstrates the stability of the TMSS bond.

(C) Fabricating Thermoelectric Unicouples using the Titanium-Molybdenum Eutectoid Reaction using Low Pressure (10 MPa)

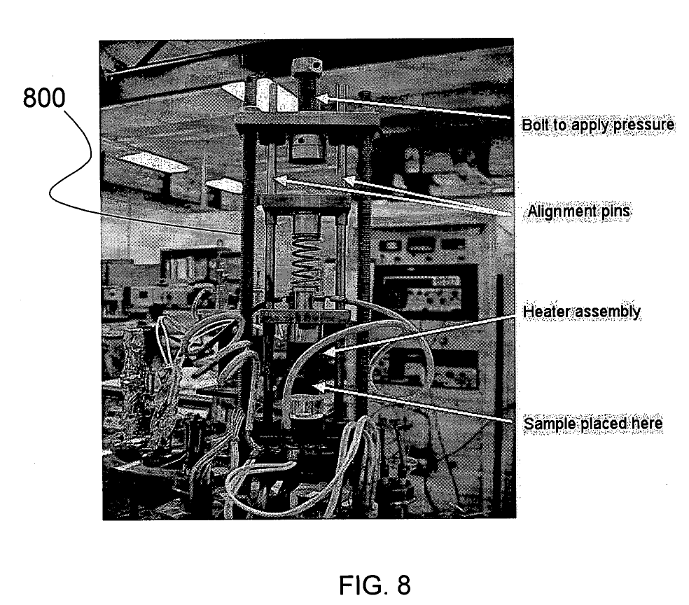

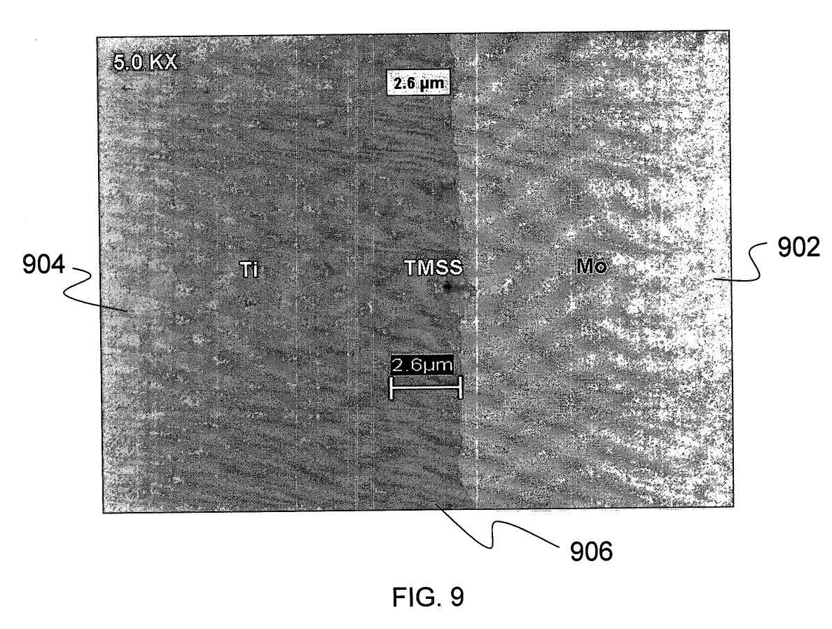

Bonding unicouples using a hot press as described above may not be a suitable process for mass producing unicouples or fabricating multi-leg arrays or modules. Thus, to improve process-ability a low-pressure alternative method was developed. An apparatus 800 was fabricated, as shown in the photograph in FIG. 8, which could apply low pressure (1 MPa as opposed to 100 MPa in the hot-press) heat through conduction to >700 C and maintain precise alignment. Molybdenum plates were bonded to Titanium plates each 2.0 mm thick and square in shape with a cross section 1.0 centimeter squared (cm²). Since this technique involves bonding two dense samples (as opposed to the Molybdenum plate/Titanium powder combination used in the hot-press process), extra care was taken to provide intimate contact between the two plates. Thus, the bonding surfaces were polished down with a one micron paste to a “mirror” finish. The plates were then rinsed with acetone to remove any organic residue. A 550 micron thermocouple access hole was drilled in the Molybdenum plate, which was stacked on top of the Titanium plate; the stack was then installed in the apparatus. The sample was heated to 720 C, held at 720 C for 100 minutes and cooled. Several samples were made using this process, the cross-section of one of which is shown in FIG. 9. As with the hot-pressed samples, a crack-free bond between the Molybdenum 902 and Titanium 904 was made. Interestingly, the TMSS intermediate layer 906 was noticeable (greater than 2 microns) unlike the as-pressed samples prepared using the hot press. This result indicated that excellent bonds could be made without requiring high pressure (100 MPa). The mutual affinity between Molybdenum and Titanium was sufficient to form strong bonds at relatively low pressure (1 MPa).

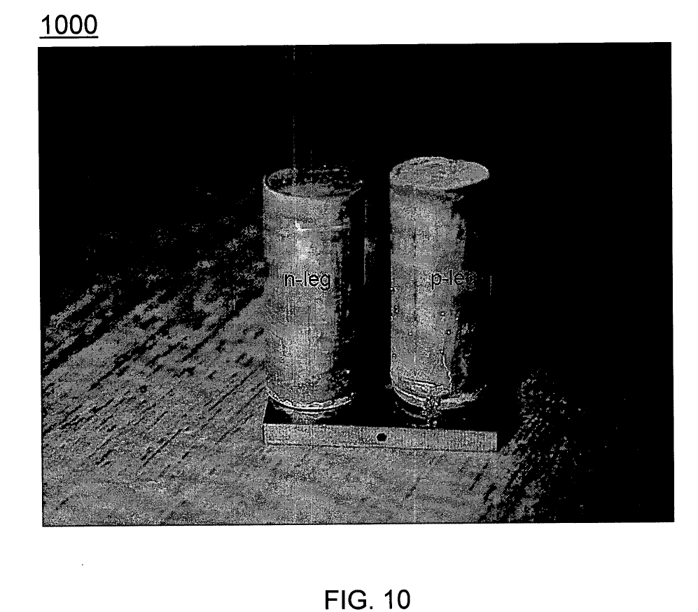

Upon demonstrating that Molybdenum/Titanium coupons could be bonded using the apparatus shown in FIG. 8, Skutterudite unicouples were fabricated. 6.3 mm diameter n and p-type legs Skutterudite legs were individually fabricated in the hot-press. To suppress sublimation of Antimony (which could interfere with the bonding process) the legs were wrapped with Graphite foil and bailed with Niobium wire. The legs were bonded to the Molybdenum plate one at a time. The resulting unicouple 1000, as shown in FIG. 10, is the first example of a Skutturedite unicouple bonded using this low pressure process.

It is important to note that similar bonding with Titanium-Niobium (Ti—Nb), Titanium-Palladium (Ti—Pd), and Titanium-Graphite have also been shown to work as well as the Titanium-Molybdenum reaction. One skilled in the art will also appreciate that the aforementioned process and materials can be used to fabricate any complexity of thermoelectric devices including thermoelectric multicouples.

(2) Process for Integrating High Density Aerogel into Thermoelectric Devices

As discussed in U.S. application Ser. No. 10/977,276, filed Oct. 29, 2004, currently pending, entitled “System and Method for Sublimation Suppression Using Opacified Aerogel” and incorporated herein by reference, aerogel can be positioned around the elements of a thermoelectric module to suppress sublimation and mitigate heat loss. Aerogel adds minimal mass to a device, mitigates parasitic heat loss, and does not cause excessive thermomechanical stress.

A novel process for integrating aerogel as a sublimation-suppression agent and thermal insulation for the thermoelectric technology has been developed. The process involves the fabrication of composite aerogels, which are primarily composed of oxide powders, with a silica aerogel working as a binder to “glue” the particles together.

The primary purpose for adding the oxide powder is to reduce shrinkage during gelation and the supercritical drying process. Reducing shrinkage is key when considering aerogel as a cast-in-place sublimation suppression coating or thermal insulation. By minimizing shrinkage, intimate contact can be made between the thermoelectric elements and the sublimation suppression coating of aerogel, thus providing efficient sublimation suppression and thermal insulation. This process yields another advantage by allowing more flexibility in processing, which provides the ability to tailor the properties of aerogel for better sublimation suppression and thermal insulation. For example, this method enables casting high density aerogel with little shrinkage (typically associated with fabrication of higher density aerogel >100 milligrams per cubic centimeters (mg/cc)). The greater the density of aerogel, the greater its ability to suppress sublimation.

Preliminary results with pure Antimony (Sb) at 500 C indicate that this new composite aerogel can suppress Sb sublimation by as much as 500 times. Therefore, this novel process will enable the casting of high density aerogel free of cracks and with significantly improved sublimation in practically all thermoelectric technologies used for power generation.

Incorporating a large quantity of particles can result in an effect similar to making composite. Particles are solid, which do not shrink and can enhance the mechanical strength of the aerogel network. Shrinkage of aerogel can be reduced by using aerogel mainly as a binder, not as the primary constituent.

(A) Aerogel Synthesis

Aerogel synthesis is based on the two act sol-gel process. The first step is to make a silica sol composed of tetraethylorthosilicate (TEOS), ethanol, and nitric acid through refluxing. The second step is to combine other components for the composite aerogel. Fumed silica (325 mesh powder with approximately 200 m²/g surface area), silica powder (1 to 2 micrometers (μm)), titania powder (1 to 2 μm) are suspended in acetonitrile and then silica sol, water, ammonia hydroxide base are added into acetonitrile with suspended powders. The amount of each component can be altered depending on the application. Fumed silica was added in order to enhance networking and titania was added as a opacifying agent. The total density was controlled by the amount of silica powder. Silica aerogel was kept at a density of 40 milligrams per cubic centimeter (mg/cc) in order to minimize the shrinkage of the silica aerogel. After gelation, samples were transferred into an acetonitrile autoclave and supercritically dried at 295 C and 5.5 MPa.

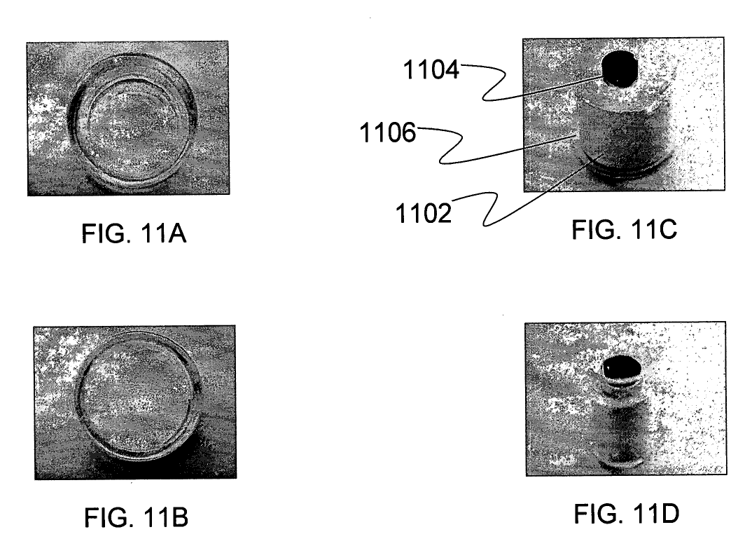

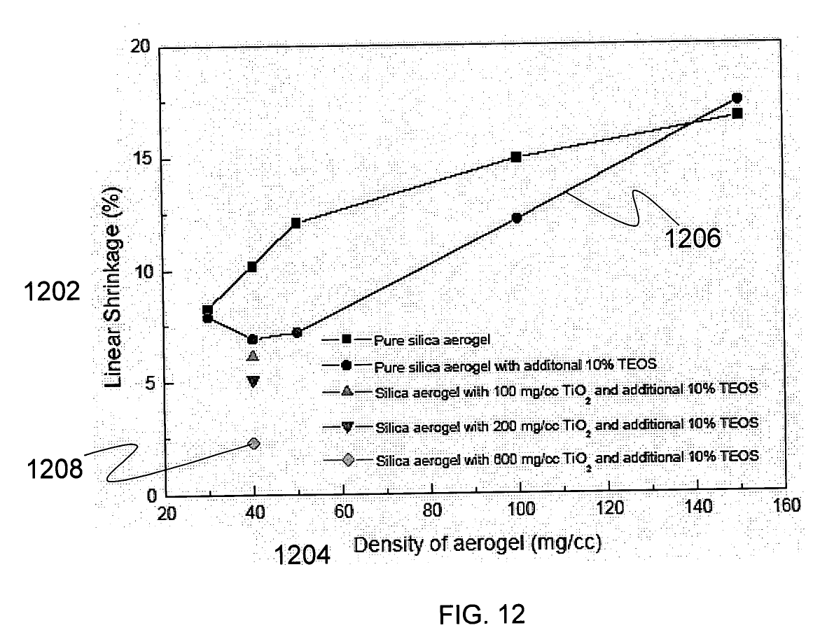

The effect of solid particles on the shrinkage of aerogels was investigated by changing the amount of titania powder and density of silica aerogel. Aerogels for shrinkage measurement were cast into quartz molds and mold release was applied to the wall of quartz molds for aerogels to shrink without constraint. Linear shrinkage was measured by comparing the diameter between the quartz molds and aerogels after supercritical drying. Linear shrinkage of pure silica aerogel is approximately 10 percent with low density (30 to 50 mg/cc) and the shrinkage increases to approximately 15 percent if the density exceeds 100 mg/cc. FIGS. 11A-11D depict aerogels showing different shrinkage. FIG. 11A shows 12 percent shrinkage with 40 mg/cc pure silica aerogel; FIG. 11B shows approximately 2 percent shrinkage with additional TEOS and 600 mg/cc titanium dioxide (TiO₂) powder into 40 mg/cc silica aerogel; FIGS. 11C and 11D show the high-density, crack-free aerogel coatings 1102 (40 mg/cc silicon dioxide (SiO₂), 200 mg/cc titanium dioxide (TiO₂)) encapsulating 6 mm dummy graphite legs 1104 in a glass mold 1106. FIG. 12 is a graph depicting the percentage of shrinkage 1202 in comparison to the density of aerogel 1204. One way to decrease shrinkage is to add additional 10 percent TEOS into the solution before gelation (line represented by 1206), but the shrinkage is more than approximately 10 percent if density of aerogel is higher than 100 mg/cc. By adding titania powder up to a concentration of 600 mg/cc into 40 mg/cc silica aerogel 1208, the shrinkage decreases from 6.9 percent to 2.3 percent. Furthermore, this is a new approach to produce aerogel with total density higher than 100 mg/cc and shrinkage of less than 5 percent.

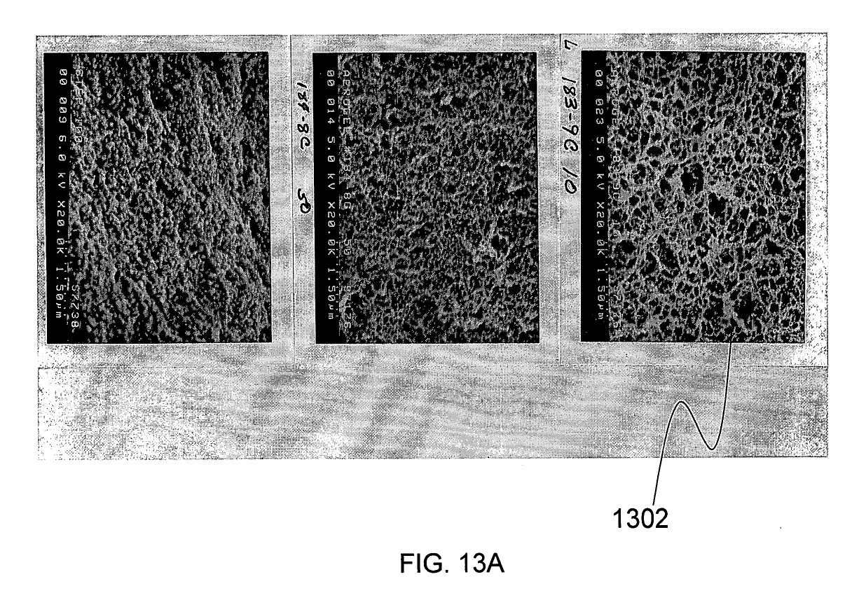

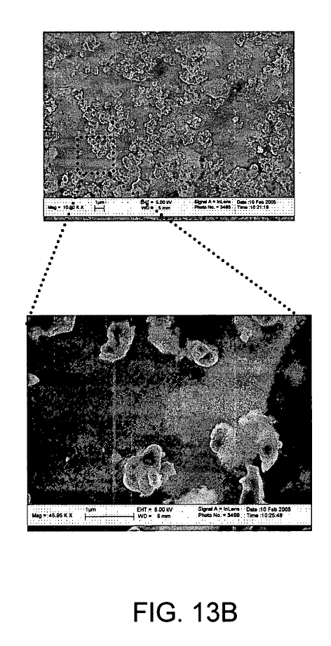

The structure of aerogel with titania powder (40 mg/cc silica aerogel and 200 mg/cc titania powder) was observed with a scanning electron micrograph (“SEM”) and the structure was compared to pure silica aerogels with different density. As shown in FIG. 13, 10 mg/cc pure silica aerogel is composed of pores with several different diameters ranging from nanometer to micrometer. Specifically, a large pore size can be a relatively easy pathway for sublimation; thus, it is generally desirable to eliminate the large size pores. As the density of aerogel increases (from right to left in FIG. 13A), most pores in the aerogel becomes less than 100 nanometers (nm) in diameter. FIG. 13B depicts a composite aerogel with 200 mg/cc titania and also shows the structure with smaller pores when compared to a SEM picture of the 50 mg/cc pure silica aerogel 1302 of FIG. 13A. Titania powders of micrometer size seem to fill large pores in silica aerogel. Although further detailed characterization is needed, it can be said that average pore size of aerogel decreases with increasing total density either by increasing density of silica aerogel or by adding solid powders.

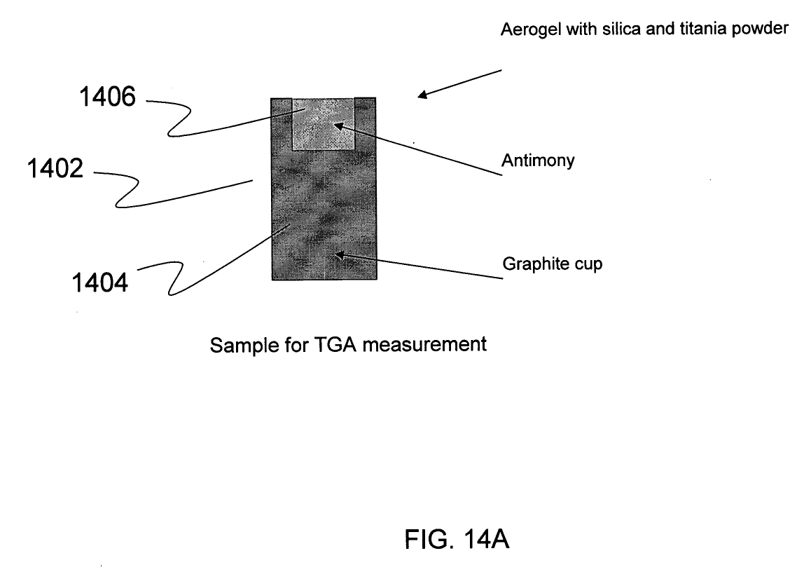

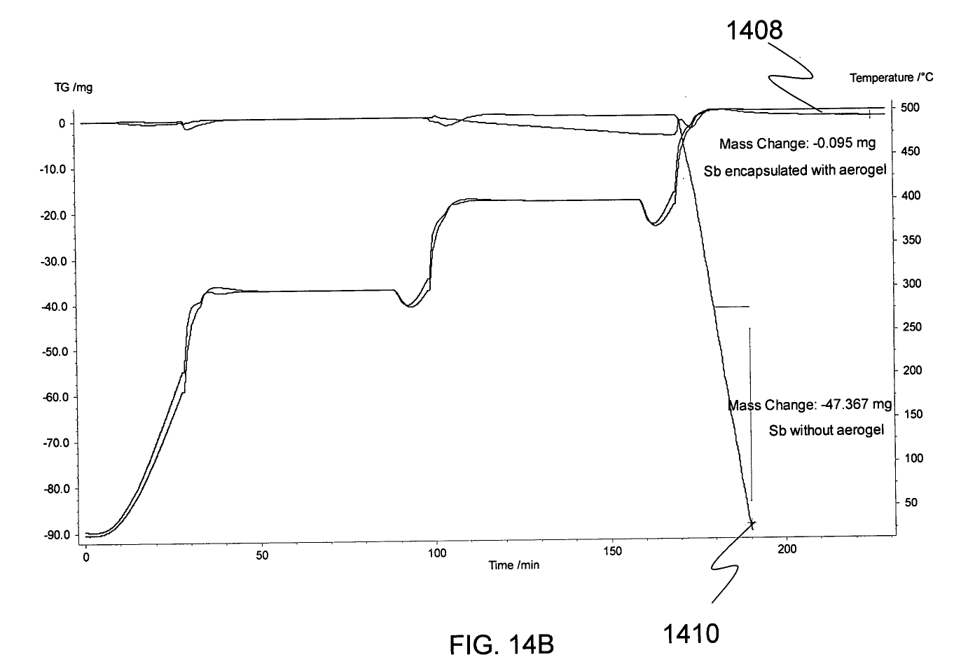

Sublimation of antimony (Sb) through a composite aerogel was measured with thermogravimetric analysis (“TGA”) and compared with the sublimation rate without aerogel. Antimony transport through aerogel is important to understand, because Sb is the main subliming species in the researched thermoelectric material (skutterudite) and sublimation is one of main degradation of thermoelectric materials. Two samples were prepared for comparison. One is only Sb powder and the other is Sb powder with aerogel encapsulation. Sb powder 1402 was pressed inside 6 mm graphite cups 1404 and then one graphite cup with Sb powder was encapsulated with aerogel 1406 (40 mg/cc silica aerogel, 60 mg/cc fumed silica, 100 mg/cc silica powder, and 50 mg/cc titania powder) as shown in FIG. 14A. Due to the new method to reduce shrinkage, it is possible to make crack free aerogel encapsulation. After preparing samples, weight loss was measured with TGA under dynamic vacuum (<1×10⁻⁵ Torr). Temperature was increased at the rate of 10 C/minute and three isothermal plateaus for measuring weight loss were set up for 1 hrs at 300 C, 400 C and 500 C. TGA profiles of both Sb samples with/without aerogel are plotted in FIG. 14B. As shown in FIG. 14B, two TGA profiles show significantly different weight loss. If weight losses of Sb with aerogel 1408 and without aerogel 1410 are compared at 500 C, there is approximately 500 times difference between them, which means that aerogel can lower the sublimation of Sb by as much as 500 times.

(3) Development of Vaporizable Scaffolds for Fabricating Thermoelectric Modules

To form a layer of the new opacified aerogel onto the surface of a thermoelectric device, a novel apparatus has been devised that involves the use of a vaporizable polymer scaffold during the thermoelectric module (“TEM”) fabrication process. The polymer scaffold serves as a temporary separator during TEM assembly and is simply vaporized during the bonding process, which occurs at elevated temperatures (>700 C) under high vacuum.

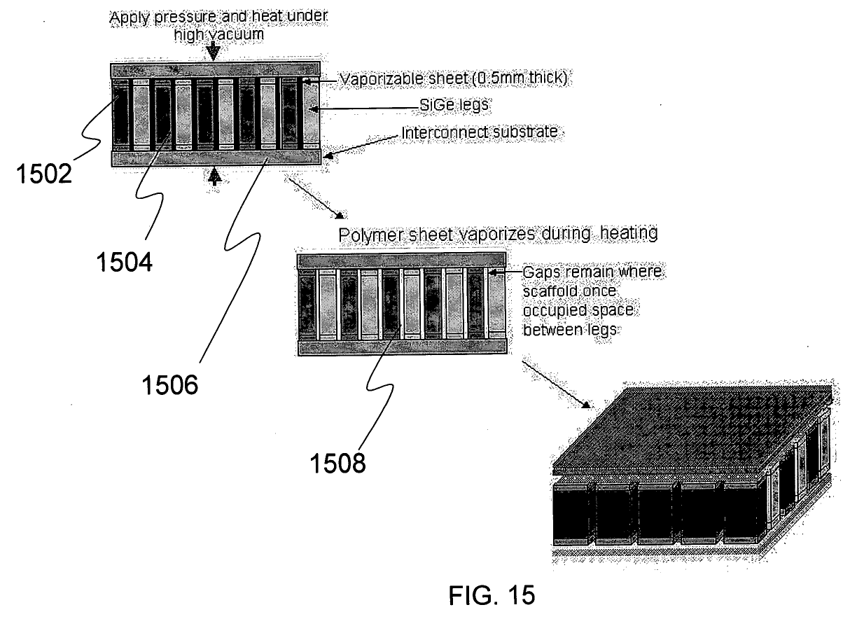

Fabrication of TEMs with 500 micron gaps between the legs can be achieved through the use of vaporizable scaffolds. Basically, thermoelectric legs 1502 are bonded to thin (approximately 500 microns), rigid polymer sheets 1504 separating them, as shown in FIG. 15. The polymer sheets 1504 keep the thermoelectric legs 1502 in position before uniaxial pressure is applied and the temperature is increased. Once uniaxial pressure is applied the increased temperature vaporizes the polymer sheets 1504. Further heating promotes bonding between the thermoelectric legs and the metal pads on the interconnect substrate 1506. The polymer is specifically selected such that it vaporizes completely before it pyrolizes (converts to carbon), which can cause short-circuiting. The stack arrangement resembles a “checker board” pattern and is aligned with electrical pads patterned on a ceramic substrate. The entire stack is then heated under uniaxial pressure. As it is heated, the polymer sheets 1504 vaporize leaving gaps 1508 in their place. It is important to note that the uniaxial pressure keeps the thermoelectric legs 1502 in place as the polymer vaporizes.

(A) Polymer Selection

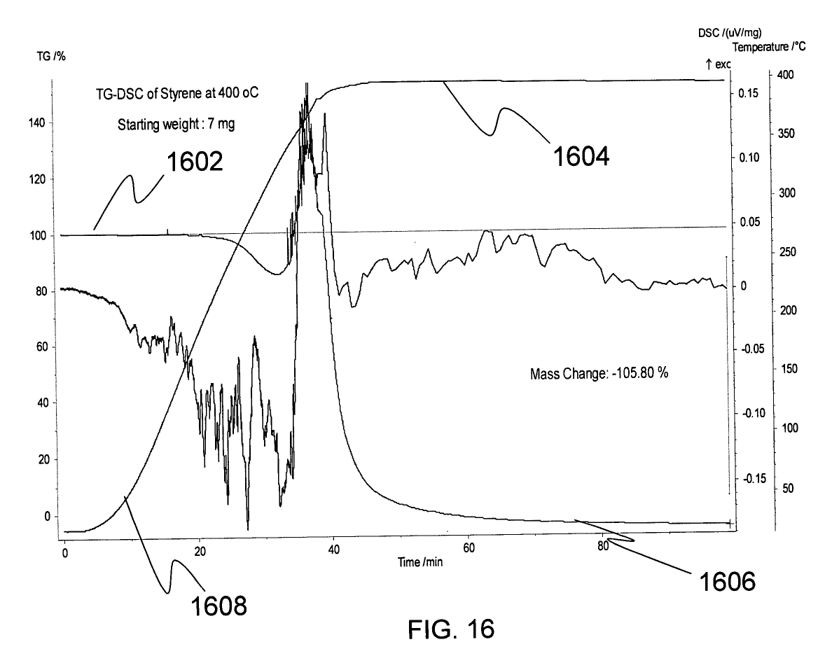

Ideally, the polymer should be rigid for precise dimensional stability and should also vaporize at a temperature below the pyrolysis temperature. Poly-α-methylstyrene (“PAMS”) was selected as a promising candidate. PAMS is considered to be rigid and it vaporizes between 250 and 400 C under 10⁻⁶ torr. The Thermal Gravimetric Analysis (“TGA”) confirms this, as shown in FIG. 16. Weight is represented by line 1602, and temperature by line 1604. Curve 1606 represents the weight loss, and curve 1608 represents the temperature. At 250 C the mass appears to increase, but this is a buoyancy phenomenon associated with the rapid loss of mass in high vacuum. Once the temperature reaches 400 C the sample mass loss is 100 percent, thus indicating complete vaporization without residual carbon associated with pyrolysis.

(B) Experimental Results

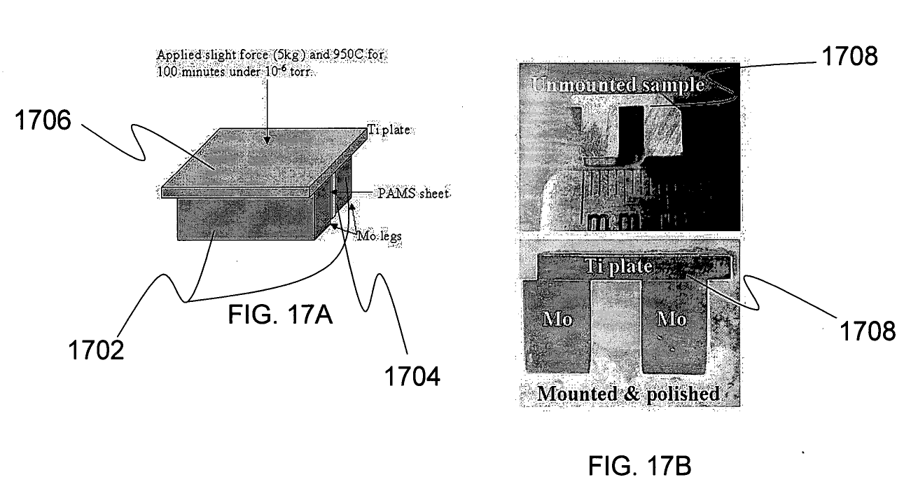

The primary concern in using the vaporizable scaffold is the possibility of polymer vapor residue interfering with the bonding of thermoelectric legs to the metal pads on the ceramic substrate. To investigate this, an experiment was conducted, which simulated the envisioned bonding configuration. A likely configuration involves thermoelectric legs terminated with Molybdenum and the metal pads on the ceramic substrate terminated with Titanium. Essentially, the two bonding interfaces will be Molybdenum and Titanium. To closely simulate this configuration, a mock-up consisting of two Molybdenum legs 1702 (6 mm high, 8.25 mm long, 3.45 mm wide), as shown in FIG. 17A, were bonded to a Titanium plate 1704 and separated by a sheet of PAMS 1706 (Scientific Polymer, Inc., molecular weight=300,000, 20 percent concentration in benzene). The mock-up parts were heated using a spring-loaded assembly, which applied approximately 5 kg of force, at 950 C under 10⁻⁶ torr vacuum. Strong, uniform bonds 1708 were made between the Molybdenum legs and the Titanium plate, as depicted in the pictures in FIG. 17B, thus demonstrating that the PAMS vapor did not interfere with bonding.

(C) Actual Use Conditions

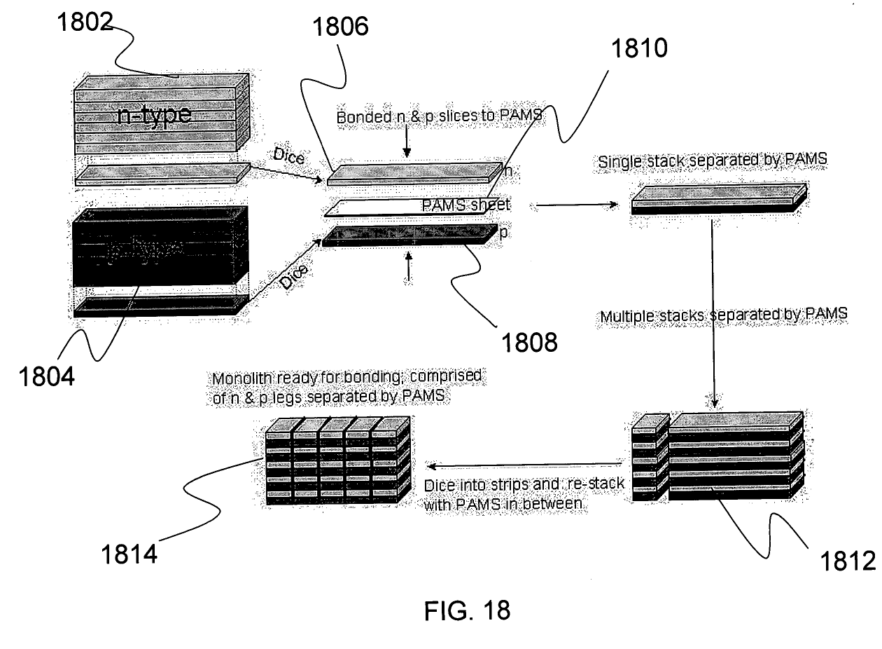

The proof-of-concept experiments represent a small-scale mock-up of an actual TEM. The TEMs will likely consist of 20 by 20 arrays of legs. The envisioned use of the PAMS scaffold in its simplest form is described in FIG. 18. Ingots of n-type 1802 and p-type 1804 thermoelectrics can be diced into wafers. The n-type wafers 1806 and p-type wafers 1808 are stacked and separated by sheets of PAMS 1810. PAMS can be bonded to metal-like surfaces using PAMS in liquid form (this has been demonstrated by dissolving PAMS in benzene solvent to bond PAMS sheet to SiGe sheets). Individual stacks can be further stacked 1812, bonded and separated using additional PAMS sheets. These parallel stacks are then diced perpendicularly and re-bonded and separated using PAMS sheets to form a “checker board” pattern 1814. At this point the array is monolithic and can be aligned with the metal pads on the ceramic substrate. The entire stack is then heated under uniaxial pressure to vaporize the PAMS and bond the legs to the metal pads.

What is claimed is:

1. A durable high-efficiency thermoelectric device comprising a thermoelectric skutterudite device bonded with a strong, low-contact resistance, high-temperature bond on a hot-side interconnect.

2. The durable high-efficiency thermoelectric device as set forth in claim 1, wherein the thermoelectric skutterudite device is bonded using a eutectoid reaction of powders selected from the group consisting of titanium and molybdenum (Ti—Mo), titanium-niobium (Ti—Nb), titanium-palladium (Ti—Pd), and titanium-graphite.

3. The durable high-efficiency thermoelectric device as set forth in claim 1, wherein the thermoelectric skutterudite device is bonded using a eutectoid reaction of pre-formed plates selected from the group consisting of titanium and molybdenum (Ti—Mo), titanium-niobium (Ti—Nb), titanium-palladium (Ti—Pd), and titanium-graphite.

4. A method for fabricating durable high-efficiency thermoelectric devices comprising acts of:
inserting a plate into an opening of a graphite die;
pressing a first thermoelectric leg onto the plate through a press hole in the graphite die to create a bond between the first thermoelectric leg and the plate;
removing the plate and now bonded first thermoelectric leg and rotating the plate before reinserting the plate into the graphite die, wherein the first thermoelectric leg is inserted into a relief hole in the graphite die; and
pressing a second thermoelectric leg onto the plate through the press hole to create a bond between the second thermoelectric leg and the plate.

5. The method as set forth in claim 4, wherein the thermoelectric skutterudite device is formed using a hot press applying approximately 100 MegaPascals (MPa) of pressure at approximately 700 degrees Celsius (C.).

6. The method as set forth in claim 4, wherein the thermoelectric skutterudite device is formed using a plate press applying only approximately 1 MPa of pressure at approximately 700 C.

7. The method as set forth in claim 4, wherein the plate is made of molybdenum.

8. The method as set forth in claim 4, wherein the first thermoelectric leg is formed of an n-type material.

9. The method as set forth in claim 8, wherein the first thermoelectric leg is formed of titanium, n-type skutterudite, titanium powder and nickel powder.

10. The method as set forth in claim 4, wherein the second thermoelectric leg is formed of a p-type material.

11. The method as set forth in claim 10, wherein the second thermoelectric leg is formed of titanium, cobalt, p-type skutterudite, titanium and nickel.

12. A high density shrink-resistant aerogel comprising a composite aerogel primarily comprised of an oxide powder to prevent shrinkage during formation in a supercritical drying process.

13. The high density shrink-resistant aerogel as set forth in claim 12, wherein the density of the composite aerogel is greater than 100 milligrams per cubic centimeter (mg/cc).

14. The high density shrink-resistant aerogel as set forth in claim 12, wherein the composite aerogel is formed from tetraethylorthosilicate (“TEOS”), ethanol, nitric acid, and titania powder.

15. The high density shrink-resistant aerogel as set forth in claim 14, wherein the titania powder is comprised roughly micrometer-sized particles.

16. A method for creating a gap between thermoelectric legs comprising an act of forming a vaporizable scaffold around a portion of a thermoelectric leg during formation of a thermoelectric element, wherein the vaporizable scaffold vaporizes during the formation of the thermoelectric element to create a gap separating a first thermoelectric leg from a second thermoelectric leg, such that the gap can be filled with an insulating material.

17. The method as set forth in claim 16, wherein the vaporizable scaffold comprises a polymer.

18. The method as set forth in claim 17, wherein the polymer is Poly-a-methylstyrene (“PAMS”).

19. The method as set forth in claim 16, wherein the insulating material is an aerogel.
